(19) United States
(12) Patent Application Publication
(10) Pub. No.: US 2006/0102076 A1
(43) Pub. Date: May 18, 2006

(54) Apparatus and method for the deposition of silicon nitride films

(75) Inventors: Jacob W. Smith, Santa Clara, CA (US); Sean M. Seutter, San Jose, CA (US); R. Suryanarayanan Iyer, St. Paul, MN (US); Binh Tran, San Jose, CA (US); Alexander Tam, Union City, CA (US); James K. Wilson, New Fairfield, CT (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/245,758

(22) Filed: Oct. 7, 2005

Related U.S. Application Data
(63) Continuation-in-part of application No. 10/911,208, filed on Aug. 4, 2004.
(60) Provisional application No. 60/525,241, filed on Nov. 25, 2003.

(51) Int. Cl. C23C 16/00

(52) U.S. Cl. 118/715; 427/248.1

(57) ABSTRACT

A method and apparatus for a chemical vapor deposition (CVD) chamber provides uniform heat distribution, uniform distribution of process chemicals in the CVD chamber, and minimization of by-product and condensate residue in the chamber. The improvements include a processing chamber comprising a chamber body, a base, and a chamber lid defining a processing region, a substrate support disposed in the processing region, a gas delivery system mounted on a chamber lid, the gas delivery system comprising an adapter ring and two blocker plates that define a gas mixing region, and a face plate fastened to the adapter ring, an exhaust system mounted at the base, a heating element positioned to heat the adapter ring; and a heating element positioned to heat a portion of the exhaust system.

### CROSS-REFERENCE TO RELATED APPLICATIONS

This application is a continuation in part of U.S. patent application Ser. No. 10/911,208, (APPM/007395) filed Aug. 4, 2004, which claims benefit of U.S. Provisional Patent Application Ser. No. 60/525,241 (APPM/007395L), filed Nov. 25, 2003, which applications are herein incorporated by reference.

### BACKGROUND OF THE INVENTION

1. Field of the Invention

Embodiments of the present invention generally relate to substrate processing. More particularly, the invention relates to chemical vapor deposition chambers and processes.

1. Description of the Related Art

Chemical vapor deposited (CVD) films are used to form layers of materials within integrated circuits. CVD films are used as insulators, diffusion sources, diffusion and implantation masks, spacers, and final passivation layers. The films are often deposited in chambers that are designed with specific heat and mass transfer characteristics to optimize the deposition of a physically and chemically uniform film across the surface of a multiple circuit carrier such as a substrate.

Chemicals for depositing CVD films may be selected for their ability to react quickly at low temperature and provide films with more uniform crystalline structure, low dielectric constant (k), and improved stress profile. Low dielectric constant films are desirable for many applications, including improved Miller capacitance in a spacer stack for improved drive current for the complementary metal oxide semiconductor (CMOS). Improving the control of stress of the deposited film and the resulting drive current of the negative metal oxide semiconductor (NMOS) is an important research goal. Also, there is a need for reducing particle formation within the chamber.

Deposition chambers are often part of a larger integrated tool to manufacture multiple components on the substrate surface. The chambers are designed to process one substrate at a time or to process multiple substrates. Historically, thermal CVD was performed by heating the substrate support to temperatures above 700° C. When performing CVD at high temperatures, the influx of heat to the chamber was the primary design parameter. Current CVD processes operate at lower temperatures to limit the thermal energy applied to the wafers and avoid undesirable results. However, lower temperatures for CVD requires improving heat distribution at the lower temperatures and providing more efficient heat and chemical distribution within the CVD chamber.

As new process chemistries are introduced for low temperature deposition, for example, a liquid silicon source such as bis(tertiary butylamino)silane, residue due to condensation and byproduct deposition becomes a chamber cleaning challenge. Hardware design is selected to minimize residue formation and accumulation to reduce production interruption and to reduce substrate particulate contamination.

Therefore, there is a need for a method and apparatus for tailoring chemicals and processes to provide rapid thermal chemical vapor deposition (RTCVD) and low pressure chemical vapor deposition (LPCVD) to form improved silicon containing films with low substrate contamination and with fast manufacturing and cleaning time requirements.

### SUMMARY OF THE INVENTION

The present invention comprises a method and apparatus for a CVD chamber that provides uniform heat distribution; uniform distribution of process chemicals, and minimization of residue in the chamber. Minimizing residue in the CVD chamber includes improvements to chamber and process kit surfaces, remote plasma generation, gas delivery and divert lines, isolation and throttle valves, and exhaust system. The improvements include a processing chamber comprising a chamber body, a base, and a chamber lid defining a processing region, a substrate support disposed in the processing region, a gas delivery system mounted on a chamber lid, the gas delivery system comprising an adapter ring and one or more blocker plates that define a gas mixing region, and a face plate fastened to the adapter ring, an exhaust system mounted at the base, a heating element positioned to heat the adapter ring, and a heating element positioned to heat a portion of the exhaust system. Optionally, a continuous purge through the remote plasma generator may be selected.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional view of one embodiment of a chamber.

FIG. 2 is a perspective schematic view of an alternative embodiment of the process kit for a single wafer thermal CVD process chamber and a liquid delivery system for process gas delivery to a chamber.

FIG. 3 is a perspective view of an embodiment of a gas delivery system.

FIG. 4 is an exploded view of various components of a process kit.

FIG. 5 is a top view of a face plate of the invention.

FIG. 6 is a sectional view of one embodiment of an exhaust system.

FIG. 7 is a cross sectional view of one embodiment of a throttle valve heater.

FIG. 8 is a perspective view of an exhaust pumping plate.

FIG. 9 is a perspective view of a cover for an exhaust pumping plate.

FIG. 10 is a perspective view of a slit valve liner.

FIG. 11 is a schematic view of a surface of a substrate that shows where samples were collected across the surface of the substrate.

### DETAILED DESCRIPTION

Embodiments of the invention provide apparatus and methods for depositing a layer on a substrate. The hardware discussion including illustrative figures of an embodiment is presented first. An explanation of process modifications and test results follows the hardware discussion. Chemical vapor deposition (CVD), sub-atmospheric chemical vapor deposition (SACVD), rapid thermal chemical vapor deposition (RTCVD), and low pressure chemical vapor deposition (LPCVD) are all deposition methods that may benefit from the following apparatus and process modifications. Examples of CVD processing chambers that may utilize some of the embodiments of this apparatus and process include SiNgen™, SiNgen-Plus™, and FlexStar™ chambers which are commercially available from Applied Materials, Inc. of Santa Clara, Calif.

Apparatus

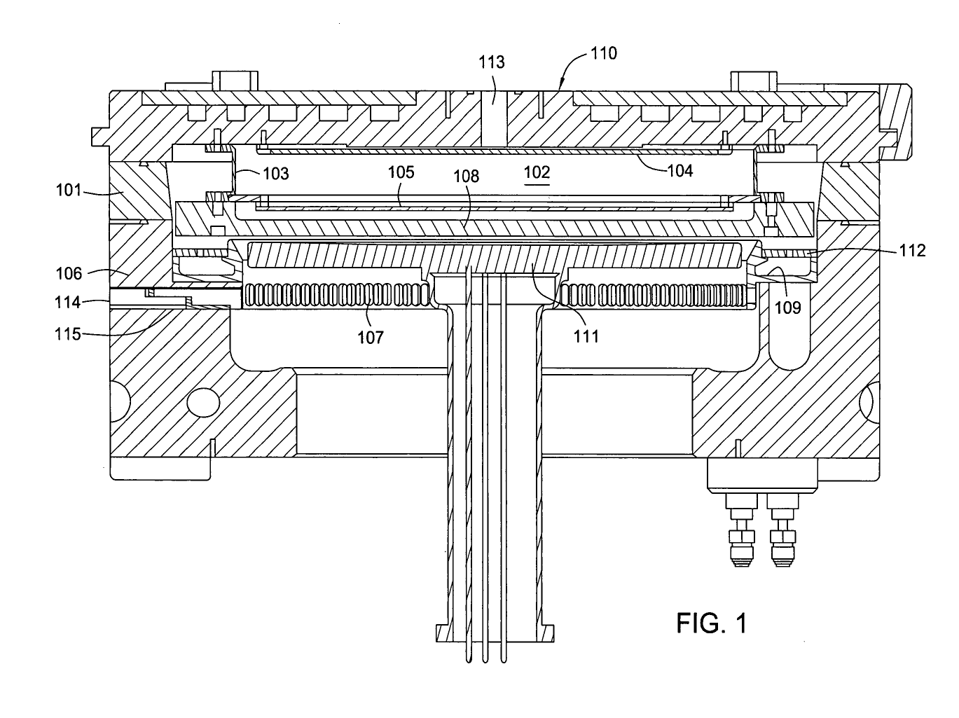

FIG. 1 is a cross sectional view of an embodiment of a single wafer CVD processing chamber having a substantially cylindrical wall 106 closed at the upper end by a lid 110. The lid 110 may further include gas feed inlets, a gas mixer, a plasma source, and one or more gas distribution plates described below. Sections of the wall 106 may be heated. A slit valve opening 114 is positioned in the wall 106 for entry of a substrate.

A substrate support assembly 111 supports the substrate and may provide heat to the chamber. In addition to the substrate support assembly, the base of the chamber may contain additional apparatus further described below, including a reflector plate, or other mechanism tailored to facilitate heat transfer, probes to measure chamber conditions, an exhaust assembly, and other equipment to support the substrate and to control the chamber environment.

Feed gas may enter the chamber through a gas delivery system before passing through a mixer 113 in the lid 110 and holes (not shown) in a first blocker plate 104. The feed gas then travels through a mixing region 102 created between a first blocker plate 104 and a second blocker plate 105. The second blocker plate 105 is structurally supported by an adapter ring 103. After the feed gas passes through holes (not shown) in the second blocker plate 105, the feed gas flows through holes (not shown) in a face plate 108 and then enters the main processing region defined by the chamber wall 106, the face plate 108, and the substrate support 111. Exhaust gas then exits the chamber at the base of the chamber through the exhaust pumping plate 107. Optionally, the chamber may include an insert piece 101 between the chamber walls 106 and the lid 110 that is heated to provide heat to the adaptor ring 103 to heat the mixing region 102. Another hardware option illustrated by FIG. 1 is the exhaust plate cover 112, which rests on top of the exhaust pumping plate 109. Finally, an optional slit valve liner 115 may be used to reduce heat loss through the slit valve opening 114.

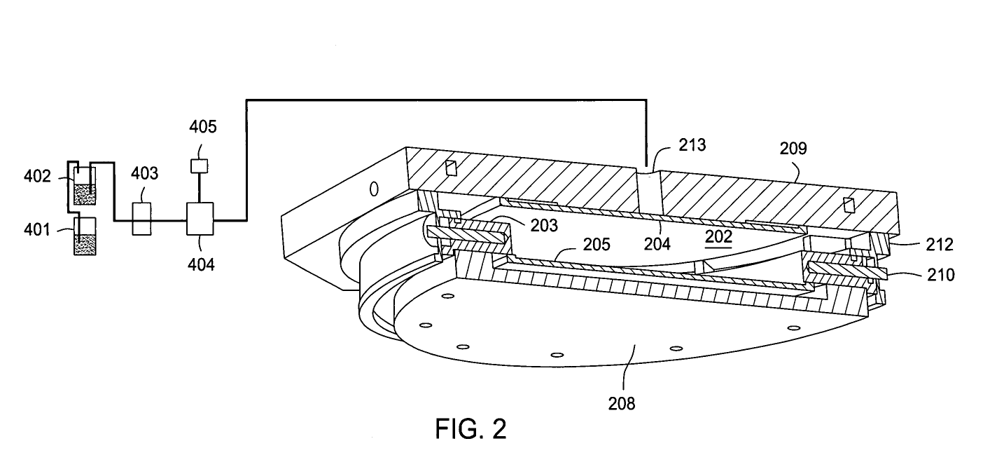

FIG. 2 is an expanded view of an alternative embodiment of the lid assembly. The lid 209 may be separated from the rest of the chamber by thermal insulating break elements 212. The break elements 212 are on the upper and lower surface of heater jacket 203. The heater jacket 203 may also be connected to blocker plate 205 and face plate 208. Optionally, parts of the lid or lid components may be heated.

The lid assembly includes an initial gas inlet 213 to premix the feed gas before entering a space 202 defined by the lid 209, the thermal break elements 212, the heater jacket 203, and the blocker plates 204 and 205. The space 202 provides increased residence time for the reactant gases to mix before entering the substrate processing portion of the chamber. Heat that may be applied by the heater 210 to the surfaces that define the space 202 helps prevent the buildup of raw materials along the surfaces of the space. The heated surfaces also preheat the reactant gases to facilitate better heat and mass transfer once the gases exit the face plate 208 and enter the substrate processing portion of the chamber.

FIG. 2 is also an illustration of the components of a gas feed system for adding an silicon containing compound such as bis(tertiary butylamino)silane (BTBAS) to a CVD chamber. The BTBAS is stored in a bulk ampoule 401. The BTBAS flows from the bulk ampoule 401 to the process ampoule 402 and then flows into the liquid flow meter 403. The metered BTBAS flows into a vaporizer 404, such as a piezo-controlled direct liquid injector. Optionally, the BTBAS may be mixed in the vaporizer 404 with a carrier gas such as nitrogen from the gas source 405. Additionally, the carrier gas may be preheated before addition to the vaporizer. The resulting gas is then introduced to the gas inlet 213 in the lid 209 of the CVD chamber. Optionally, the piping connecting the vaporizer 404 and the mixer 113 may be heated.

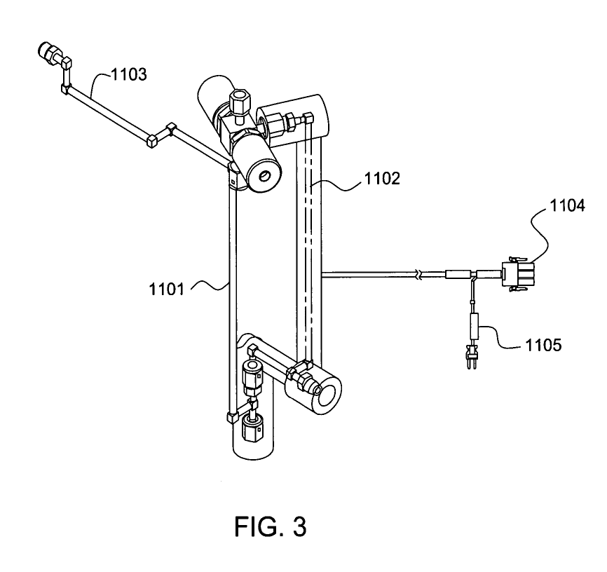

FIG. 3 is a three dimensional view of an embodiment of a gas delivery system. The precursor gas is delivered to the system through line 1103. The clean and vent line 1101 divides the precursor gas from the heated divert line 1102. Portions of the gas and fluid mixture that flow through the heated divert line 1102 flow through convection gauge 1104 and exhaust 1105.

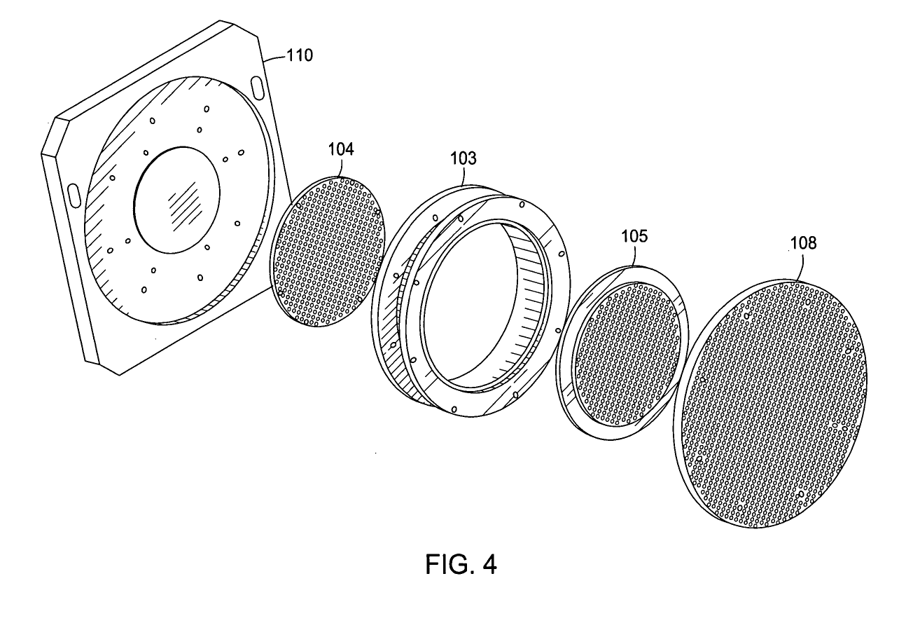

FIG. 4 is an exploded view of the embodiments of the gas feed system shown in FIG. 1. FIG. 4 illustrates how the lid 110, one or more blocker plates 104,105, the adaptor ring 103, and the face plate 108 may be configured to provide a space with heated surfaces for heating and mixing the gases before they enter the processing region of the chamber.

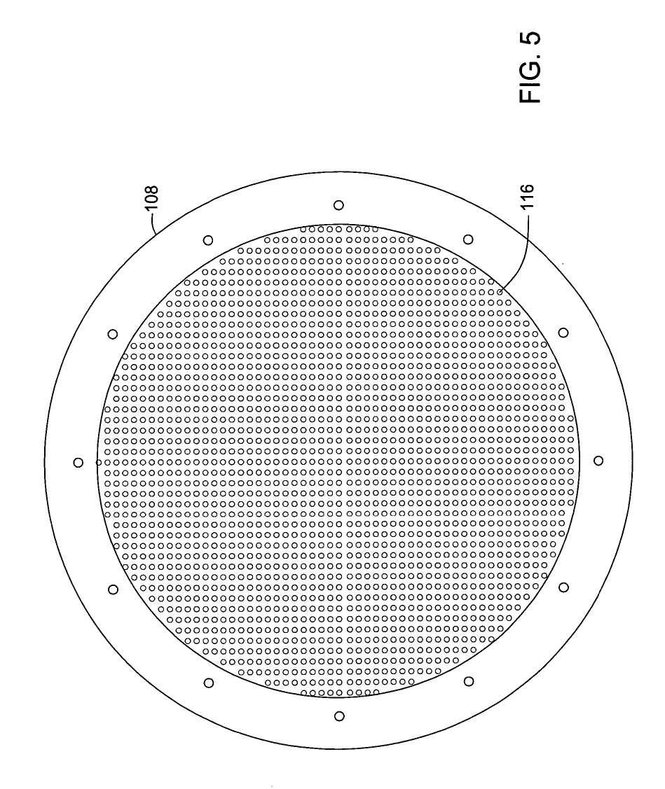

FIG. 5 is an illustration of an embodiment of the face plate 108 of FIG. 1. The face plate 108 is supported by the adapter ring 103. The face plate 108 is connected to the adapter ring 103 by screws and is configured with holes 116 arranged to create a desirable gas inlet distribution within the processing region of the chamber.

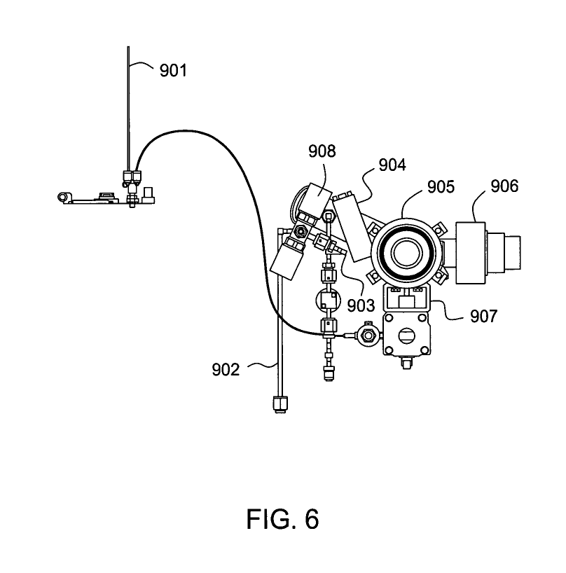

FIG. 6 is a sectional view of an embodiment of an exhaust system. Conduit 901 supplies clean dry air to dilute the final exhaust gas as it enters an abatement system. The precursor gas line has a clean or vent line 902 and divert line 903. The convection gauge 904 is in communication with the divert line 903 and ball valve 905. The ball valve 905 is in communication with the throttle valve 906 and the spool piece 907. Ball valve 905 may be a ball type ISO valve or a JALAPEÑO™ valve. JALAPEÑO™ valves are compact heated vacuum valves and are commercially available from HPS Products of Wilmington, Mass. A valve heater supplies heat to the ball valve 905.

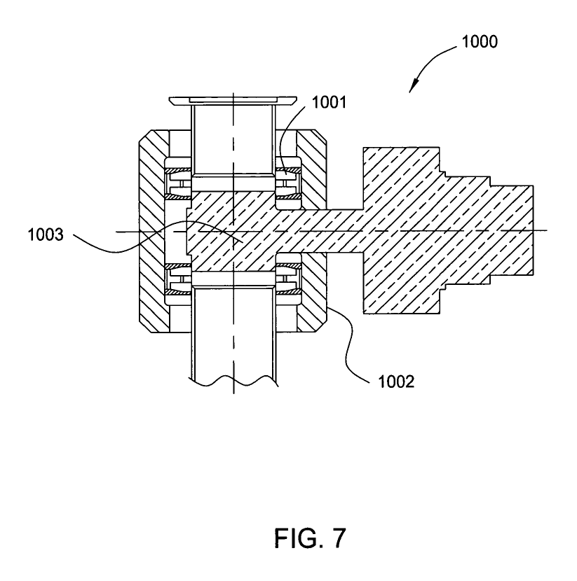

FIG. 7 provides a cross sectional view of an embodiment of a throttle valve 1000. Clamps 1001 extend around the valve 1000. Throttle valve heater jacket 1002 provides heat to the exterior of valve 1000, indirectly heating the cavity 1003 of the valve 1002.

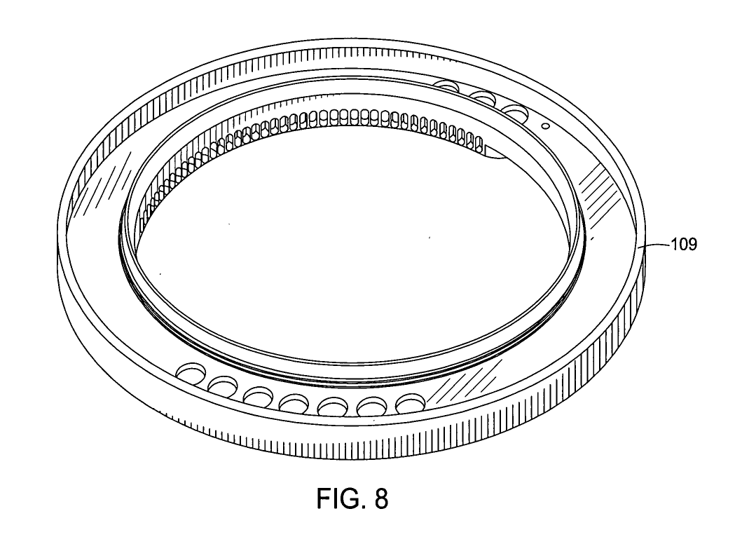

FIG. 8 is a three dimensional schematic view of one embodiment of the exhaust pumping plate 109 to control the flow of exhaust from the processing region of the chamber. A section of exhaust pumping plate 109 consisting of a skirt, shown as a series of slit-shaped holes, help compensate for heat loss at the slit valve area.

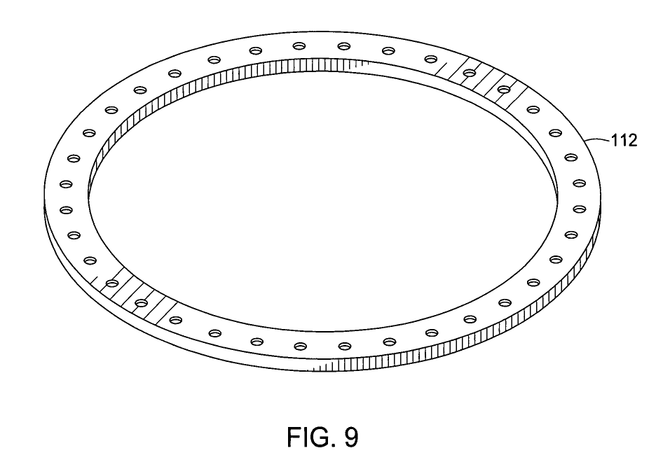

FIG. 9 is a three dimensional schematic view of an exhaust plate cover 112 for the exhaust plate 109. The cover 112 is designed with optimized, nonuniform holes to provide even gas distribution or alternatively to provide purposely uneven gas distribution to compensate for heat loss imbalance.

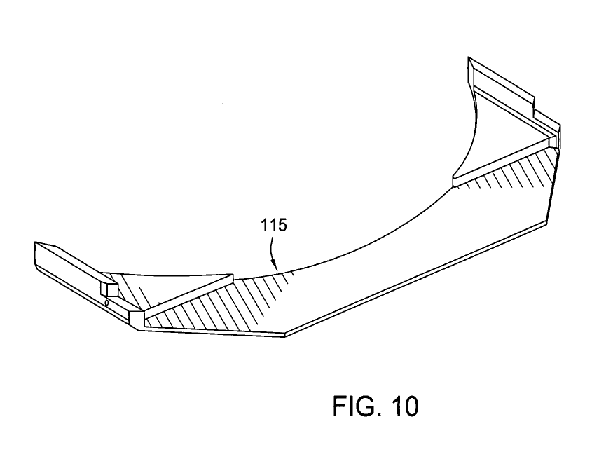

FIG. 10 is a three-dimensional view of one embodiment of the slit valve liner 115 of FIG. 1. The slit valve liner 115 reduces heat loss through the slit valve opening 114 by directing process gas flow and reducing heat transfer through the slit valve.

In operation, within the processing region of the chamber below the face plate 108, 208, heat distribution is controlled by supplying heat to surfaces such as the face plate, the walls of the chamber, the exhaust system, and the substrate support. Heat distribution is also controlled by the design of the skirted exhaust plate, the optional insertion of a exhaust plate cover, and the optional insertion of a slit valve liner. Chemical distribution within the processing portion of the chamber is influenced by the design of the face plate, the exhaust plate, and the optional exhaust plate cover. Plasma cleaning is also improved when the face plate is heated.

Continuous Purge

The gas delivery system may also be modified to feature continuous purge of a remote plasma generator. Argon or other inert gas may be selected for the continuous purge. Diluent gas provides another mechanism for tailoring film properties. Nitrogen or helium is used individually or in combination. Hydrogen or argon may also be used. Heavier gas helps distribute heat in the chamber. Lighter gas helps vaporize the precursor liquids before they are added to the chamber. Sufficient dilution of the process gases also helps prevent condensation or solid deposition on the chamber surfaces.

Continuously purging the remote plasma generator with argon was tested by comparing a system using 1 slm Ar purge to a system with no argon purge. The build-up of deposits after using BTBAS to deposit films on 4000 wafers with no purge was visually significant. The deposits engulfed the seal in communication with the remote plasma generator and gas distribution assembly. In contrast, the system using 1 slm Ar in combination with BTBAS had no visually detectable deposit formation. Mathematical modeling of the purge supports estimating that a 1 slm Ar purge substantially reduces back streaming and increasing the Ar purge above 2 slm reduces mixing near the chamber inlet. Thus, the optimum flow rate of Ar to purge the system is estimated at about 1 to about 2 slm. The change in the performance of the deposition of the BTBAS based film was not adversely influenced by the Ar purge.

Examples of films that may be deposited in the CVD chambers described herein are provided below. The overall flow rate of gas into the chambers may be 200 to 20,000 sccm and typical systems may have a flow rate of 4,000 sccm. The film composition, specifically the ratio of nitrogen to silicon content, refractive index, wet etch rate, hydrogen content, carbon content, and stress of any of the films presented herein, may be modified by adjusting several parameters. These parameters include the temperature, pressure, total flow rates, substrate position within the chamber, and heating time. The pressure of the system may be adjusted from 10 to 350 Torr and the concentration ratio of NH₃ to BTBAS may be adjusted from 0 to 10.

Gas Delivery

Several modifications may be made to the gas delivery system to improve heat transfer properties. The faceplate 108 is heated to prevent chemical deposition on the surface of the faceplate, preheat the gases in the chamber, and reduce heat loss to the lid. The adaptor ring 103 that attaches the faceplate to the lid helps thermally isolate the faceplate from the lid. For example, the lid may be maintained at a temperature of about 30-70° C., while the faceplate may be maintained at a temperature of about 150 to 300° C. The adapter ring may be designed with uneven thickness to restrict heat loss to the lid, acting like a thermal choke. The thermal separation of the faceplate from the lid protects the faceplate from the temperature variations that may be present across the surface of the lid. Thus, the faceplate is less likely to lose heat to the lid than conventional chambers and can be maintained at a higher temperature than faceplates of conventional chambers. The more uniform gas heating provided by the faceplate results in a more uniform film deposition on a substrate in the chamber. One observed advantage of a higher temperature faceplate is a higher film deposition rate in the chamber. It is believed that a higher temperature for the faceplate enhances deposition rates by accelerating the dissociation of the precursors in the chamber. Another advantage of a higher faceplate temperature is a reduced deposition of CVD reaction byproducts on the faceplate.

A repeatability test was performed to examine the effects of having a larger space between the gas inlet and final gas distribution plate. The film layer thickness for a film deposited in a conventional chamber and a modified chamber that features increased volume between the gas inlet and final gas distribution plate were compared. Significant, unexpected improvements in wafer uniformity were observed with the modified chamber.

Substrate Support

The substrate support assembly 111 has several design mechanisms to encourage uniform film distribution. The support surface that contacts the substrate may feature multiple zones for heat transfer to distribute variable heat across the radius of the substrate. For example, the substrate support assembly may include a dual zone ceramic heater that may be maintained at a process temperature of 500-800° C., for example 600-700° C. The substrate temperature is typically about 20-30° C. cooler than the measured heater temperature. The support may be rotated to compensate for heat and chemical variability across the interior of the processing portion of the chamber. The support may feature horizontal, vertical, or rotational motion within the chamber to manually or mechanically center the substrate within the chamber.

Exhaust System

The exhaust system also contributes to heat and chemical distribution in the chamber. The pumping plate 109 may be configured with unevenly distributed openings to compensate for heat distribution problems created by the slit valve. The pumping plate may be made of a material that retains heat provided to the processing portion of the chamber by the substrate support assembly to prevent exhaust chemical deposition on the surface of the plate. The pumping plate features multiple slits placed strategically to also compensate for the slit valve emissivity distortion. Other parts of the exhaust system that may be heated include the clean and/or vent line 902, the divert line 903, the iso valve 908, convection gauge 904, ball valve 905, spool piece 907, and throttle valve 906. The divert line and vent lines may be heated to about 65° C. The throttle valve and iso valve may be heated to about 145° C. The exhaust system also helps maintain a pressure of 10 to 350 Torr in the chamber.

Also, providing heat to the chamber exhaust surfaces decreased the likelihood of deposit formation. Experiments showed that heating the divert line eliminated condensate formation along the line. Heating the throttle valve and using a heated JALAPEÑO ™ design eliminated or dramatically reduced residue formation due to condensation and by-product formation when tested for 3000 substrates compared to one month of unheated operation. Heating the chamber isolation valve and using a ball design eliminated or dramatically reduced residue associated with condensation and by-product formation, eliminating clogging and malfunctioning of the valve over more than 4500 substrates and reducing variability of the valve position compared to a month of service of an unheated system. A heated ball ISO valve had visually no deposits after 3000 substrates compared to substantial deposits for the unheated ball ISO valve.

UV Lamps

Additionally, the gas delivery system may be modified to include a UV lamp system to excite the process gases, for example, ammonia. U.S. patent application Ser. No. 11/157,533 filed Jun. 21, 2005 provides details for a UV lamp system for use during dielectric deposition and chamber clean and is incorporated by reference herein.

Chamber Surfaces

The surfaces of the processing chamber may be made of anodized aluminum. The anodized aluminum discourages condensation and solid material deposition. The anodized aluminum is better at conducting heat than many substances, so the surface of the material remains warmer and thus discourages condensation or product deposition. The material is also less likely to encourage chemical reactions that would result in solid deposition than many conventional chamber surfaces. The lid, walls, spacer pieces, blocker plates, face plate, substrate support assembly, slit valve, slit valve liner, and exhaust assembly may all be coated with or formed of solid anodized aluminum.

The advantages of the hardware modifications include extended time between disconnecting the system and clean the individual components, reduced particle formation and reduced substrate contamination. Furthermore, the process can be performed at a wider window of process conditions, including depositing films at a lower substrate support temperature. The hardware can be used with processes that were designed for use with higher substrate support temperatures.

Silicon Nitride Films

Silicon nitride films may be chemical vapor deposited in the chambers described herein by reaction of a silicon precursor with a nitrogen precursor. Silicon precursors that may be used include dichlorosilane (DCS), hexachlorodisilane (HCD), bis(tertiary butylamino)silane (BTBAS), silane (SiH₄), disilane (Si₂H₆), and many others. Nitrogen precursors that may be used include ammonia (NH₃), hydrazine (N₂H₄), and others. For example, SiH₄ and NH₃ chemistry may be used.

In the CVD processing chamber, SiH₄ dissociates into SiH₃, SiH₂ primarily, and possibly SiH. NH₃ dissociates into NH₂, NH, and H₂. These intermediates react to form SiH₂NH₂ or SiH₃NH₂ or similar amino-silane precursors that diffuse through the gas boundary layer and react at or very near the substrate surface to form a silicon nitride film. It is believed that the warmer chamber surfaces provide heat to the chamber that increases NH₂ reactivity. The increased volume of the space between the gas inlet in the lid of the chamber and the second blocker plate increases the feed gas residence time and the probability of forming desired amino-silane precursors. The increased amount of the formed precursors reduces the probability of pattern micro-loading, i.e. the depletion of the precursors in densely patterned areas of the substrate.

It was also found that increasing the NH₃ flow rate relative to the flow rate of the other precursors improved pattern micro-loading. For example, conventional systems may operate with flow rates of NH₃ to SiH₄ in a ratio of 60 to 1. Test results indicate a conventional ratio of 60 to 1 to 1,000 to 1 provides a uniform film when spacing between the lid and the faceplate is increased. It was further found that using a spacing of 850-1,000 mils between the faceplate and the substrate enhanced the film uniformity compared to films deposited at 650 mm.

Carbon Doped Silicon Nitride Films

In one embodiment, bis(tertiary butyl) aminosilane, BTBAS, may be used as a silicon containing precursor for deposition of carbon doped silicon nitride films in the chambers described herein. The following is one mechanism that may be followed to produce a carbon doped silicon nitride film with t-butylamine byproducts. The BTBAS may react with the t-butylamine to form isobutylene.
3C₈H₂₂N₂Si+NH₃=>Si₃N₄+NH₂C₄H₉

The BTBAS reaction to form the carbon doped silicon nitride film may be reaction rate limited, not mass transfer limited. Films formed on a patterned substrate may uniformly coat the exposed surfaces of the patterned substrate. BTBAS may have less pattern loading effect than the conventional silicon precursors such as silane. It is believed that the pattern loading effect experienced with silicon containing precursors such as silane is due to the mass transfer limitations of those precursors.

Using BTBAS as a reactant gas also allows carbon content tuning. That is, by selecting operating parameters such as pressure and precursor gas concentration, the carbon content of the resulting film may be modified to produce a film with higher or lower carbon concentration across a substrate. BTBAS may be added to the system at a rate of 0.05 to 2.0 gm/min and typical systems may use 0.3-0.6 g/min.

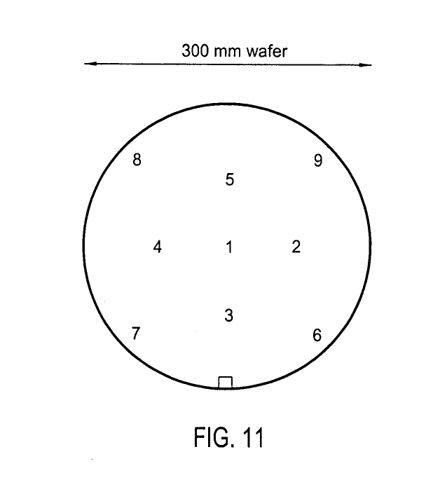

Table 1 gives an element by element composition of samples taken from various points across a substrate for different process conditions. The element composition of the samples was measured by nuclear reaction analysis and Rutherford backscattering spectroscopy. FIG. 11 is a drawing of a substrate showing where the samples were collected across the surface of the substrate. For example, location 1 data represented the information at the center of the substrate. Location 9 data represents data collected at the periphery of the substrate, and location 4 represents data collected across the midpoint of the radius of the substrate.

TABLE 1
Atomic Composition Based on Location across Substrate
Surface

| | C | N | O | Si |
|---|---|---|---|---|
| Slot 3, Spot 1 (0 mm, 0 deg.) | 10.8 | 37.4 | 6.4 | 45.3 |
| Slot 3, Spot 2 (75 mm, 0 deg.) | 10.5 | 37.5 | 6.6 | 45.4 |
| Slot 3, Spot 3 (75 mm, 90 deg.) | 10.5 | 37.4 | 6.8 | 45.4 |
| Slot 3, Spot 4 (75 mm, 180 deg.) | 10.8 | 37.6 | 6.7 | 45.0 |
| Slot 3, Spot 5 (75 mm, 270 deg.) | 10.7 | 38.1 | 6.7 | 44.5 |
| Slot 3, Spot 6 (145 mm, 45 deg.) | 11.1 | 37.6 | 6.7 | 44.7 |
| Slot 3, Spot 7 (145 mm, 135 deg.) | 10.0 | 37.8 | 6.5 | 45.7 |
| Slot 3, Spot 8 (145 mm, 225 deg.) | 10.4 | 37.6 | 6.3 | 45.6 |
| Slot 3, Spot 9 (145 mm, 315 deg.) | 11.2 | 37.1 | 6.9 | 44.8 |
| Average | 10.7 | 37.6 | 6.6 | 45.2 |
| St. Dev. | 0.4 | 0.3 | 0.2 | 0.4 |
| % St. Dev. | 3.4 | 0.7 | 2.9 | 0.9 |

Table 1 illustrates that the variation in carbon content across the surface of the substrate was 3.4% based on XPS testing results. It was found that carbon doped silicon nitride films having from 2 to 18 atomic percentage carbon were deposited at enhanced rates in the chambers described herein.

Using BTBAS as the silicon containing precursor offers several resulting film property advantages. Increasing the carbon content of the film can improve the dopant retention and junction profile, resulting in improved performance in the positive channel metal oxide semiconductor (PMOS) part of the device. The process parameters may also be tailored when combined with the use of BTBAS to facilitate improved stress profile. Enhanced film stress improves the device performance for the negative channel metal oxide semiconductor (NMOS) part of the device. Film stress properties are influenced by tailoring the chamber pressure, total feed gas flow, the NH₃ and BTBAS feed gas ratio, and the volume of BTBAS.

Additional experimental results indicate that at 675° C. the standard deviation for film thickness was 1.5 percent. The particle contamination was less than 30 particles at less than or equal to 0.12 μm. The wet etch ratio was measured as less than 0.3. The wet etch ratio of the film to a thermal oxide with 100:1 HF. RMS roughness at 400 Å is equal to 0.25 nm. The film deposition rate over 625 to 675° C. was 125 to 425 Å/min. The deposition rate was higher when higher concentration of BTBAS, lower NH₃ concentration, and higher pressure and temperature were selected. The hydrogen concentration of the film was less than 15 percent. Hydrogen is mostly bonded within the film as N—H.

The observed stress was 1 E9 to 2 E10 dynes/cm² (0.3 to 1.7 GPa) for an enhanced NMOS I-drive. The stress was higher with high concentrations of NH₃, low concentration of BTBAS, and low pressure.

The measured refractive index over the same temperature range was 1.8 to 2.1. The refractive index was higher when the system was operated at lower pressure and lower BTBAS concentration.

Also, the observed or estimated carbon concentration ranged from 2 to 18 percent. It was highest when the NH₃ concentration was low and the concentration of BTBAS was high.

Finally, an additional analysis was performed using three BTBAS configurations. Table 2 provides flow rates, concentration, and resulting film properties for three configurations.

TABLE 2
Three BTBAS configurations and the resulting film properties.

| | | C 5-6% | C 8-9% | C 12-13% |
|---|---|---|---|---|
| recipe | | (predicted) | (tested) | (predicted) |
| dep rate | (Ang/min) | 315.4 | 266.9 | 399.4 |
| dep time | (sec) | 136 | 160 | 106 |
| target thickness | (Ang) | 700 | 700 | 700 |
| monitor film thickness | (Ang) | 714.97 | 711.715 | 705.545 |
| monitor N/U 1-sigma | (%) | 2.371 | 1.437 | 1.492 |
| VR | | 0.98 | 0.98 | 0.98 |
| RI | | 1.821 | 1.82 | 1.817 |
| BTBAS consumption | (grams/ | 0.897 | 0.571 | 0.782 |
| | 500 Ang film) | | | |
| stress | (Gpa) | | 1.2 | |
| WERR | | | 0.5 | |
| heater temp | (C) | 675 | 675 | 675 |
| chamber pressure | (Torr) | 162.5 | 275 | 160 |
| BTBAS flow | (grams/min) | 0.566 | 0.305 | 0.625 |
| | (sccm) | 74.2 | 40 | 81.9 |
| NH₃ flow | (sccm) | 300 | 40 | 40 |
| N₂ carrier flow | (slm) | 2 | 2 | 2 |
| N₂ flow | (slm) | 1.7 | 3 | 2 |
| total top gas flow | (slm) | ˜4 | ˜5 | ˜4 |
| N₂ bottom flow | (slm) | 3 | 3 | 3 |
| spacing | (mils) | 700 | 700 | 700 |

The C 5-6% and C 12-13% configurations have predicted values. The C 8-9% values are experimental results. VR indicates the voltage ratio of different zones of the heated substrate support. RI indicates the refractive index. WERR is the wet etch rate ratio.

Four examples were tested. Pressure, temperature, spacing, flow rate, and other conditions are shown in Table 3. Column 1 shows a set of operating conditions at lower BTBAS concentration than the other examples. Column 2 shows operation at low temperature and wet etch ratio. Column 3 shows the lowest wet etch ratio and temperature and column 4 shows operating parameters for the highest pattern loading effect of the four examples. In the examples, the wafer heater temperature was 675 to 700° C. and the pressure of the chamber was 50 to 275 Torr.

TABLE 3
Operating Conditions for Testing BTBAS Performance

| recipe name | #1 | #2 | #3 | #4 |
|---|---|---|---|---|
| wafer temperature (° C.) | ˜670 | ˜655 | ˜660 | ˜675 |
| heater temp (° C.) | 675 | 675 | 675 | 700 |
| pressure (Torr) | 275 | 160 | 80 | 50 |
| NH₃ (sccm) | 80 | 80 | 80 | 80 |
| BTBAS (grams/min) | 0.61 | 1.2 | 1.2 | 1.2 |
| BTBAS (sccm) | 78 | 154 | 154 | 154 |
| N₂-carrier top (sim) | 4 | 4 | 4 | 4 |
| N₂-dep-top (sim) | 10 | 10 | 6 | 6 |
| N₂-bottom (sim) | 10 | 10 | 10 | 10 |
| spacing (mills) | 700 | 700 | 700 | 700 |
| deposition rate (A/min) | 230 | 250 | 170 | 250 |
| BTBAS consumption | 0.27 | 0.48 | 0.71 | 0.48 |
| (grams/100 A film) | | | | |
| Wet etch rate ratio (%) | 25 | 16 | 11 | 12 |
| stress (dynes/sq.cm) - 500 A film | 1.54 | 1.54 | 1.51 | 1.67 |
| RI | 1.865 | 1.885 | 1.935 | 1.985 |
| thickness 1 sigma N/U (%) | 1.55 | 1.55 | 1.50 | 1.90 |
| PLE on UMC 90 nm chip by TEM | | | | |
| sidewall (%) | 7 | 9 | 3 | 3 |
| bottom (%) | 7 | 3 | 3 | 3 |

Table 3 results may be compared to conventional and similar systems. The wet etch rate ratio test results in Table 3 may be compared to silicon oxide films deposited in conventional furnace systems which have a one minute dip in 100:1 HF deposition time in a 150 second wet etch ratio evaluation. The stress test results of Table 1 are similar to other test results for similar operating conditions that have results of 0.1 to 2.0 GPa.

Silicon Oxide and Oxynitride Films

BTBAS also offers some process chemistry flexibility. For BTBAS based oxide processes, NH₃ can be substituted by an oxidizer such as N₂O.

To manufacture a silicon oxide nitride film, BTBAS may be used with NH₃ and an oxidizer such as N₂O.

While the foregoing is directed to embodiments of the present invention, other and further embodiments of the invention may be devised without departing from the basic scope thereof, and the scope thereof is determined by the claims that follow.

1. An apparatus for deposition of a film on a semiconductor substrate, comprising;
a chamber wall, a base, and a chamber lid defining a processing region;
a substrate support disposed in the processing region;
a gas delivery system mounted on a chamber lid, the gas delivery system comprising an adapter ring and one or more blocker plates that define a gas mixing region, and a face plate fastened to the adapter ring;
an exhaust system mounted at the base;
a heating element positioned to heat the adapter ring; and
a heating element positioned to heat a portion of the exhaust system.

2. The apparatus of claim 1, wherein one of the blocker plates is fastened to the chamber lid and the other blocker plate is fastened to the adapter ring.

3. The apparatus of claim 1, wherein the gas delivery system further comprises a divert line in communication with the exhaust system.

4. The apparatus of claim 1, further comprising a slit valve liner positioned in a slit valve channel in the chamber body.

5. The apparatus of claim 1, further comprising an exhaust pumping plate surrounding the substrate support and a cover plate on the exhaust pumping plate, wherein the cover plate has optimized, non-uniformly distributed holes.

6. The apparatus of claim 1, further comprising a vaporizer in fluid communication with the mixing region.

7. The apparatus of claim 6, further comprising a heating element configured to provide heat to the vaporizer.

8. The apparatus of claim 1, wherein the exhaust system comprises a ball valve and a throttle valve.

9. The apparatus of claim 8, further comprising an ISO valve and a spool piece.

10. The apparatus of claim 9, further comprising a convection gauge.

11. The apparatus of claim 10, further comprising a clean/vent line in communication with the ISO valve.

12. The apparatus of claim 8, further comprising heating elements to supply heat to the ball valve and the throttle valve.

13. The apparatus of claim 9, further comprising heating elements to supply heat to the ISO valve and the spool piece.

14. The apparatus of claim 11, further comprising heating elements to supply heat to the clean/vent line.

15. A method for deposition of a film on a semiconductor substrate, comprising:
providing a purge gas to a remote plasma generator;
flowing the purge gas to a gas delivery system;
providing precursor gas to a remote plasma generator while continuously providing the purge gas to the remote plasma generator;
flowing both precursor gas and purge gas to a gas delivery system;
stopping the providing the precursor gas to the remote plasma generator while continuing to provide the purge gas to the remote plasma generator.

16. The method of claim 15, wherein the purge gas is selected from the group consisting of nitrogen, argon, helium, or hydrogen.

17. The method of claim 16, wherein the flow of purge gas is about 1 to about 2 slm.
